(19) United States
(12) Patent Application Publication
(10) Pub. No.: US 2008/0048641 A1
(43) Pub. Date: Feb. 28, 2008

(54) Peak voltage detector circuit and binarizing circuit including the same circuit

(75) Inventors: Yasuaki Makino, Okazaki-city (JP); Hiroshi Okada, Nukata-gun (JP); Reiji Iwamoto, Nukata-gun (JP); Norikazu Ohta, Aichi-gun (JP); Hideki Hosokawa, Owariasahi-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/822,291

(22) Filed: Jul. 3, 2007

(30) Foreign Application Priority Data
Jul. 6, 2006 (JP) 2006-186892

(51) Int. Cl. G01R 19/04

(52) U.S. Cl. 324/103 P

(57) ABSTRACT

A peak voltage detector circuit detects a peak voltage of an input voltage. The input voltage is input into a first input terminal of a comparator. A counter circuit counts up a counter value in synchronization with a first clock signal, when a signal output from the comparator is in a first state. The counter circuit counts down the counter value in synchronization with a second clock signal. A digital-analog conversion circuit outputs an output voltage corresponding to the counter value, and the output voltage is input into a second input terminal of the comparator. The first clock signal has a wave period shorter than that of the second clock signal.

### CROSS REFERENCE TO RELATED APPLICATION

This application is based on Japanese Patent Application No. 2006-186892 filed on Jul. 6, 2006, the disclosure of which is incorporated herein by reference in its entirety.

### BACKGROUND OF THE INVENTION

1. Field of the Invention

The present invention relates to a peak voltage detector circuit for detecting a peak voltage of an input voltage, and a binarizing circuit using the peak voltage detector circuit.

2. Description of Related Art

When a physical phenomenon is observed by using a sensor, a peak of a measured voltage is often used to recognize a state of the physical phenomenon. At this time, the peak of the measured voltage is detected by using a peak voltage detector circuit. The peak voltage detector circuit is included in an apparatus, which measures a rotation number and a rotation angle of an axel using a magnet sensor, for example. In this apparatus, the magnet sensor measures voltage having alternating waveform in accordance with rotation of the axle. The measured voltage having the alternating waveform is binarized, and the binarized digital signal is converted into the rotation number and the rotation angle of the axle. In order to binarize the measured voltage having the alternating waveform, an intermediate value between a positive peak voltage and a negative peak voltage of the measured voltage is calculated. The positive peak voltage is convex upward, and the negative peak voltage, i.e., bottom voltage, is convex downward. The intermediate value is used as a threshold voltage to binarize the measured voltage. Therefore, in order to accurately convert the measured voltage having the alternating waveform into the digital signal, both of the positive peak voltage and the negative peak voltage are required to be accurately measured.

JP-A-6-174756 discloses a peak voltage detector circuit 100 shown in FIG. 9, which detects a peak voltage of an input voltage. The peak voltage detector circuit 100 includes a comparator 120, an AND circuit 130, a counter circuit 140, a digital/analog (D/A) conversion circuit 150 and a first clock signal generating circuit for generating a clock signal CLK1. An input voltage V_{IN} is input into a noninversion input terminal of the comparator 120, and an output voltage V_{PEAK} output from the D/A conversion circuit 150 is input into an inversion input terminal of the comparator 120. When an output signal V_{UP} output from the comparator 120 is high, the counter circuit 140 adds its counter value in synchronization with the clock signal CLK1 by using the AND circuit 130. The D/A conversion circuit 150 outputs a voltage corresponding to the counter value of the counter circuit 140. A peak voltage of the input voltage V_{IN} is provided as the output voltage V_{PEAK} of the D/A conversion circuit 150.

FIG. 10 shows a waveform chart of the peak voltage detector circuit 100. When the input voltage V_{IN} becomes larger than the output voltage V_{PEAK}, the output signal V_{UP} of the comparator 120 becomes high. When the output signal V_{UP} of the comparator 120 is high, the AND circuit 130 inputs the clock signal CLK1 into the counter circuit 140. The counter circuit 140 adds the counter value in synchronization with the clock signal CLK1. Thereby, the output voltage V_{PEAK} of the D/A conversion circuit 150 is stepwise increased in synchronization with the clock signal CLK1. That is, when the input voltage V_{IN} is larger than the output voltage V_{PEAK}, the output voltage V_{PEAK} is stepwise increased in synchronization with the clock signal CLK1 to follow the increasing of the input voltage V_{IN}.

When the input voltage V_{IN} starts decreasing, the input voltage V_{IN} becomes smaller than the output voltage V_{PEAK}. When the input voltage V_{IN} is smaller than the output voltage V_{PEAK}, the output signal V_{UP} of the comparator 120 becomes low. Thereby, the clock signal CLK1 is not input into the counter circuit 140, so that the counter circuit 140 stops adding the counter value. Thus, the peak voltage detector circuit 100 can detect the peak voltage of the input voltage V_{IN}.

FIG. 10 shows a single wave period of the input voltage V_{IN}, and FIG. 11 shows plural wave periods of the input voltage V_{IN}. The measured voltage output from the magnetic sensor, i.e., input voltage V_{IN} of the peak voltage detector circuit 100, has a rapidly varying part and a slowly varying part, due to a temperature variation, for example. Therefore, as shown in FIG. 11, the peak voltage of the input voltage V_{IN} is slowly increased in a time period T100, and the peak voltage of the input voltage V_{IN} is slowly decreased in a time period T200, for example.

In a case where the positive peak voltage is to be detected by using the peak voltage detector circuit 100 disclosed in JP-A-6-174756, the peak voltage of the input voltage V_{IN} can be detected in every wave period of the time period T100, as shown in FIG. 11. However, while the peak voltage of the input voltage V_{IN} is gradually decreased in the time period T200, the maximum positive peak voltage hold in the time period T100 continues to be kept. Therefore, the peak voltage detector circuit 100 cannot detect the peak voltage of the input voltage V_{IN} in the time period T200.

Further, in a case where the negative peak voltage, i.e., bottom voltage, is to be detected, the bottom voltage of the input voltage V_{IN} can be detected in every wave period of the time period T200. However, the bottom voltage of the input voltage V_{IN} cannot be detected in the time period T100.

### SUMMARY OF THE INVENTION

In view of the foregoing and other problems, it is a first object of the present invention to provide a peak voltage detector circuit for detecting a peak voltage of an input voltage. It is a second object of the present invention to provide a binarizing circuit for binarizing an input voltage.

According to a first example of the present invention, a peak voltage detector circuit for detecting a peak voltage of an input voltage includes a comparator, a first clock signal generating circuit, a second clock signal generating circuit, a counter circuit and a digital-analog conversion circuit. The comparator has a first input terminal and a second input terminal, and the input voltage is input into the first input terminal of the comparator. The first clock signal generating circuit generates a first clock signal. The second clock signal generating circuit generates a second clock signal. The counter circuit counts up a counter value in synchronization with the first clock signal, when an output signal output from the comparator is in a first state. The counter circuit counts down the counter value in synchronization with the second clock signal. The digital-analog conversion circuit outputs an output voltage corresponding to the counter value of the counter circuit, and the output voltage of the digital-analog conversion circuit is input into the second input terminal of the comparator. The first clock signal has a wave period shorter than that of the second clock signal.

According to a second example of the present invention, a peak voltage detector circuit for detecting a positive peak voltage of an input voltage includes a comparator, a first clock signal generating circuit, a second clock signal generating circuit, a counter circuit and a digital-analog conversion circuit. The comparator has a noninversion input terminal and an inversion input terminal, and the input voltage is input into the noninversion input terminal of the comparator. The first clock signal generating circuit generates a first clock signal. The second clock signal generating circuit generates a second clock signal. The counter circuit adds a counter value in synchronization with the first clock signal, when an output signal output from the comparator is high. The counter circuit subtracts the counter value in synchronization with the second clock signal. The digital-analog conversion circuit outputs an output voltage corresponding to the counter value of the counter circuit, and the output voltage of the digital-analog conversion circuit is input into the inversion input terminal of the comparator. The first clock signal has a wave period shorter than that of the second clock signal.

According to a third example of the present invention, a peak voltage detector circuit for detecting a negative peak voltage of an input voltage includes a comparator, a first clock signal generating circuit, a second clock signal generating circuit, a counter circuit and a digital-analog conversion circuit. The comparator has a noninversion input terminal and an inversion input terminal, and the input voltage is input into the inversion input terminal of the comparator. The first clock signal generating circuit generates a first clock signal. The second clock signal generating circuit generates a second clock signal. The counter circuit subtracts a counter value in synchronization with the first clock signal, when an output signal output from the comparator is high. The counter circuit adds the counter value in synchronization with the second clock signal. The digital-analog conversion circuit outputs an output voltage corresponding to the counter value of the counter circuit. The output voltage of the digital-analog conversion circuit is input into the noninversion input terminal of the comparator. The first clock signal has a wave period shorter than that of the second clock signal.

According to a fourth example of the present invention, a binarizing circuit for converting an input voltage having an alternating waveform into a digital signal includes the peak voltage detector circuit of the second example, the peak voltage detector circuit of the third example and a determination circuit. The determination circuit provides a threshold voltage based on a positive peak voltage provided by the peak voltage detector circuit of the second example, and a negative peak voltage provided by the peak voltage detector circuit of the third example. The determination circuit determines the input voltage to be high or low based on the provided threshold voltage.

Accordingly, the peak voltage can be accurately detected by the peak voltage detector circuit, and the input voltage can be accurately binarized by the binarizing circuit.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic diagram showing a positive peak voltage detector circuit according to a first embodiment of the present invention;

FIG. 2 is a waveform chart of the positive peak voltage detector circuit;

FIG. 3 is a waveform chart showing plural wave periods of an input voltage to be detected by the positive peak voltage detector circuit;

FIG. 4 is a schematic diagram showing a modification of the positive peak voltage detector circuit;

FIG. 5 is a schematic diagram showing a negative peak voltage detector circuit according to the first embodiment;

FIG. 6 is a schematic diagram showing a modification of the negative peak voltage detector circuit;

FIG. 7 is a schematic diagram showing a binarizing circuit according to a second embodiment;

FIG. 8 is a waveform chart of the binarizing circuit;

FIG. 9 is a schematic diagram showing a conventional peak voltage detector circuit;

FIG. 10 is a waveform chart of the conventional peak voltage detector circuit; and

FIG. 11 is a waveform chart showing plural wave periods of an input voltage to be detected by the conventional peak voltage detector circuit.

### DETAILED DESCRIPTION OF PREFERRED EMBODIMENTS

### First Embodiment

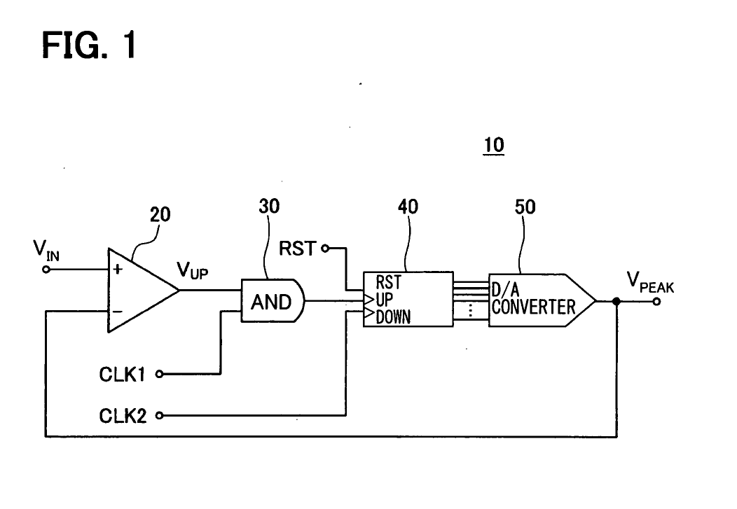

As shown in FIG. 1, a positive peak voltage detector circuit 10 for detecting a peak voltage, i.e., voltage convex upward, includes a comparator 20, an AND circuit 30, a counter circuit 40, a digital/analog (D/A) conversion circuit 50, a first clock signal generating circuit and a second clock signal generating circuit. The first clock signal generating circuit generates a first clock signal CLK1, and a wave period of the first clock signal CLK1 is shorter than that of a second clock signal CLK2 generated by the second clock signal generating circuit. Each frequency of the first clock signal CLK1 and the second clock signal CLK2 is set in accordance with a physical phenomenon of an object to be measured.

An input voltage V_{IN} is input into a noninversion input terminal of the comparator 20, and an output voltage V_{PEAK} output from the D/A conversion circuit 50 is input into an inversion input terminal of the comparator 20. The input voltage V_{IN} has an alternating waveform, and represents a measured voltage measured by a magnetic sensor disposed on an axle to measure its rotation number or rotation angle.

The AND circuit 30 has two input terminals. An output signal V_{UP} output from the comparator 20 is input into one input terminal of the AND circuit 30, and the first clock signal CLK1 is input into the other input terminal of the AND circuit 30. The AND circuit 30 outputs an output signal in synchronization with the first clock signal CLK1 when the output signal V_{UP} of the comparator 20 is high.

The counter circuit 40 is an up/down n-bit counter. An output signal output from the AND circuit 30 is input into an up-input terminal of the counter circuit 40. The second clock signal CLK2 is input into a down-input terminal of the counter circuit 40. The counter circuit 40 further has a reset-input terminal for resetting its counter value, into which a reset signal RST is input. The counter circuit 40 adds the counter value by using the AND circuit 30 in synchronization with the first clock signal CLK1 when the output signal V_{UP} of the comparator 20 is high. The counter circuit 40 subtracts the counter value in synchronization with the second clock signal CLK2.

The D/A conversion circuit 50 outputs a voltage corresponding to the counter value of the counter circuit 40. The output voltage V_{PEAK} of the D/A conversion circuit 50 is used as a positive peak voltage of the input voltage V_{IN}. Further, the output voltage V_{PEAK} of the D/A conversion circuit 50 is input into the inversion input terminal of the comparator 20.

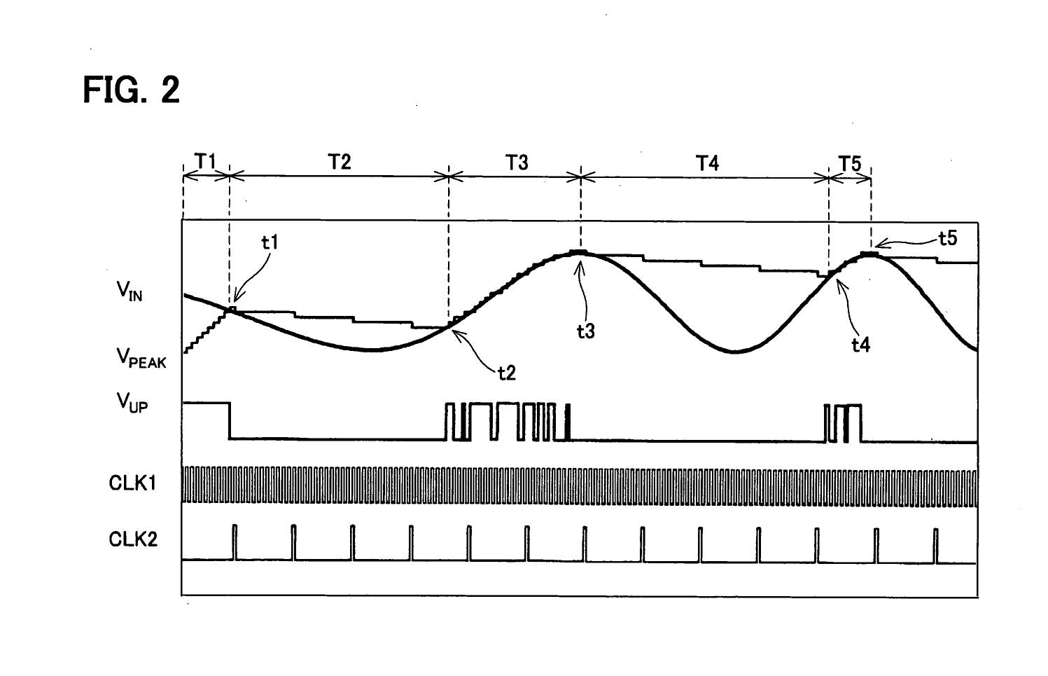

FIG. 2 shows a waveform chart of the peak voltage detector circuit 10. Each of a time period T1 and a time period T2 represents a transitional term. After the transitional term, the peak voltage detector circuit 10 operates to detect a positive peak voltage of the input voltage V_{IN}. Each of a time period T3 and a time period T5 represents a detection term, in which the positive peak voltage of the input voltage V_{IN} is detected. A time period T4 represents a characteristic term, in which the detected positive peak voltage disappears and the next positive peak voltage appears.

The time period T1 and the time period T2 will be described in details. When measurement by the peak voltage detector circuit 10 is started, the reset signal RST is input into the counter circuit 40 to initialize the counter value of the counter circuit 40. At this time, the output voltage V_{PEAK} of the D/A conversion circuit 50 is also initialized. Because an initial value of the counter value is set low, an initial value of the output voltage V_{PEAK} is also low. The initial value of the counter value is set such that the output voltage V_{PEAK} is lower than the input voltage V_{IN}. Therefore, at the measurement starting time, the output signal V_{UP} of the comparator 20 becomes high, because the input voltage V_{IN} is larger than the output voltage V_{PEAK}. The AND circuit 30 inputs the first clock signal CLK1 into the counter circuit 40 when the output signal V_{UP} of the comparator 20 is high. The counter circuit 40 adds the counter value in synchronization with the first clock signal CLK1. Thereby, the output voltage V_{PEAK} of the D/A conversion circuit 50 is stepwise increased in synchronization with the first clock signal CLK1, as shown of the time period T1 in FIG. 2.

At a timing t1, the output voltage V_{PEAK} becomes equal to the input voltage V_{IN}. Then, when the input voltage V_{IN} becomes smaller than the output voltage V_{PEAK}, the output signal V_{UP} of the comparator 20 becomes low. The AND circuit 30 stops inputting the first clock signal CLK1 into the counter circuit 40, so that the counter circuit 40 stops adding the counter value. Thus, the increasing of the output voltage V_{PEAK} is stopped. Here, the second clock signal CLK2 is input into the down-input terminal of the counter circuit 40. Therefore, the counter value of the counter circuit 40 is subtracted in synchronization with the second clock signal CLK2. Thus, the output voltage V_{PEAK} is decreased in synchronization with the second clock signal CLK2 in the time period T2.

At a timing t2, when the input voltage V_{IN} becomes larger than the output voltage V_{PEAK}, the time period T3 is started in order to detect the positive peak voltage of the input voltage V_{IN}. When the input voltage V_{IN} is larger than the output voltage V_{PEAK}, the output signal V_{UP} of the comparator 20 becomes high. When the output signal V_{UP} of the comparator 20 is high, the AND circuit 30 inputs the first clock signal CLK1 into the counter circuit 40, so that the counter circuit 40 adds the counter value in synchronization with the first clock signal CLK1. Thereby, the output voltage V_{PEAK} of the D/A conversion circuit 50 is stepwise increased in synchronization with the first clock signal CLK1. That is, when the input voltage V_{IN} is larger than the output voltage V_{PEAK}, the output voltage V_{PEAK} is stepwise increased in synchronization with the first clock signal CLK1 to follow the increasing of the input voltage V_{IN}. Here, in the time period T3, the counter value of the counter circuit 40 is subtracted in synchronization with the second clock signal CLK2. However, a wave period of the second clock signal CLK2 is much longer than that of the first clock signal CLK1. Therefore, the subtraction of the counter value due to the second clock signal CLK2 can be practically ignored in comparison with the addition of the counter value due to the first clock signal CLK1. Therefore, the output voltage V_{PEAK} is stepwise increased in synchronization with the first clock signal CLK1 to follow the increasing of the input voltage V_{IN}.

At a timing t3, when the input voltage V_{IN} starts decreasing, the input voltage V_{IN} becomes smaller than the output voltage V_{PEAK}. Then, the output signal V_{UP} of the comparator 20 becomes low, and the first clock signal CLK1 is not input into the counter circuit 40. Therefore, the counter circuit 40 stops adding the counter value. Thus, the peak voltage detector circuit 10 can detect the positive peak voltage of the input voltage V_{IN}.

In the time period T4, the counter value of the counter circuit 40 is subtracted in synchronization with the second clock signal CLK2. Therefore, the output voltage V_{PEAK} is stepwise decreased until when the next wave period of the input voltage V_{IN} appears. Because the output voltage V_{PEAK} is gradually decreased, the next wave period of the input voltage V_{IN} can secure to be detected. Even if the input voltage V_{IN} is slowly decreased, the next wave period of the input voltage V_{IN} can secure to be detected.

Then, at a timing t4, when the input voltage V_{IN} becomes larger than the output voltage V_{PEAK}, the next detection time period T5 is started in order to detect the next positive peak voltage of the input voltage V_{IN}. Description of the time period T5 is approximately similar to that of the time period T3, and description of the timing t5 is approximately similar to that of the timing t3.

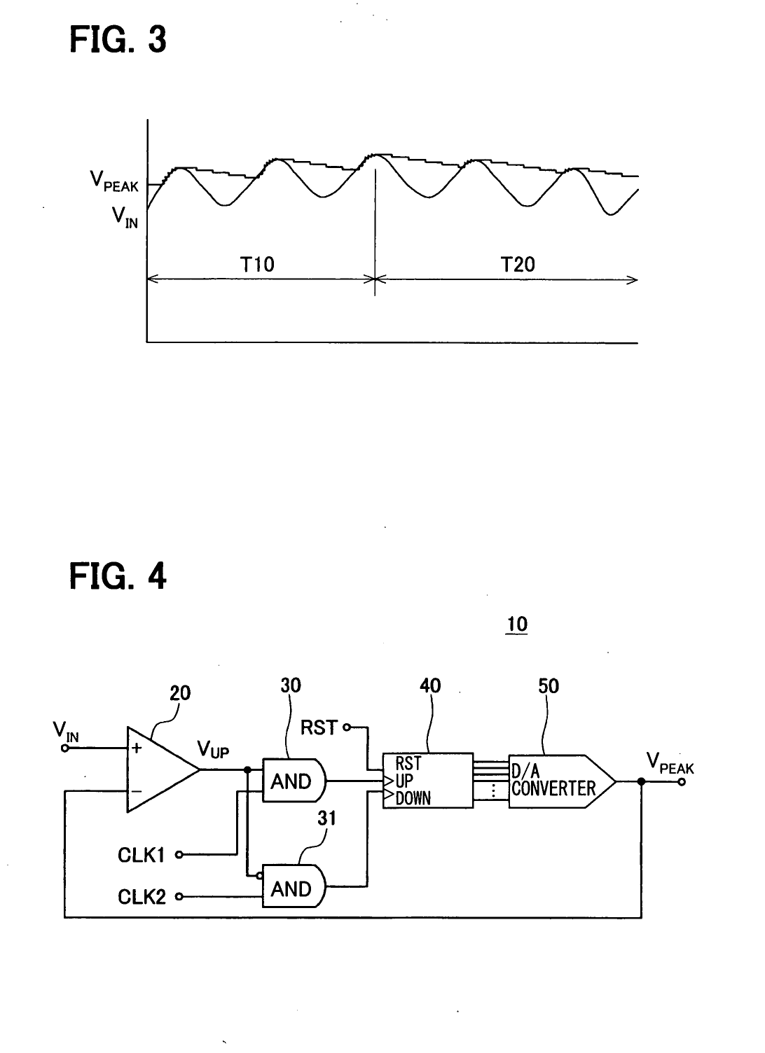

FIG. 3 shows plural wave periods of the input voltage V_{IN}. The measured voltage output from the magnetic sensor, i.e., input voltage V_{IN} of the peak voltage detector circuit 10, has a rapidly varying part and a slowly varying part due to a temperature variation, for example. Therefore, as shown in FIG. 3, the peak voltage of the input voltage V_{IN} is slowly increased in a time period T10, and the peak voltage of the input voltage V_{IN} is slowly decreased in a time period T20. The peak voltage detector circuit 10 can detect the positive peak voltage of the input voltage V_{IN} in every wave period of both of the time period T10 and the time period T20.

When the input voltage V_{IN} is larger than the output voltage V_{PEAK} of the D/A conversion circuit 50, the positive peak voltage detector circuit 10 adds the counter value of the counter circuit 40 by using the first clock signal CLK1, which has the wave period shorter than that of the second clock signal CLK2. Thus, the output voltage V_{PEAK} of the D/A conversion circuit 50 can be increased to follow a rapid increasing of the input voltage V_{IN}. Further, the positive peak voltage detector circuit 10 subtracts the counter value of the counter circuit 40 by using the second clock signal CLK2, which has the wave period longer than that of the first clock signal CLK1. Therefore, the output voltage V_{PEAK} of the D/A conversion circuit 50 can be decreased to follow a slow decreasing of the input voltage V_{IN}.

Due to the positive peak voltage detector circuit 10, the output voltage V_{PEAK} can follow both of the rapid increasing and the slow decreasing of the input voltage V_{IN} by using the first and second clock signals CLK1, CLK2. Due to the positive peak voltage detector circuit 10, the positive peak voltage of the input voltage V_{IN} can be accurately detected.

FIG. 4 shows a modification of the positive peak voltage detector circuit 10. In the modification, the circuit 10 further includes another AND circuit 31, i.e., second AND circuit 31. The second AND circuit 31 has two input terminals. An inversion signal inverted of the output signal V_{UP} of the comparator 20 is input into one input terminal of the second AND circuit 31, and the second clock signal CLK2 is input into the other input terminal of the second AND circuit 31. The second AND circuit 31 outputs an output signal in synchronization with the second clock signal CLK2 when the output signal V_{UP} of the comparator 20 is low.

According to the modification, the counter circuit 40 subtracts the counter value in synchronization with the second clock signal CLK2 when the output signal V_{UP} of the comparator 20 is low. In other words, when the output signal V_{UP} of the comparator 20 is high, that is when the input voltage V_{IN} is larger than the output voltage V_{PEAK}, the counter value of the counter circuit 40 is not subtracted. Therefore, when the input voltage V_{IN} is rapidly increased, the output voltage V_{PEAK} can accurately follow the rapid increasing of the input voltage V_{IN}.

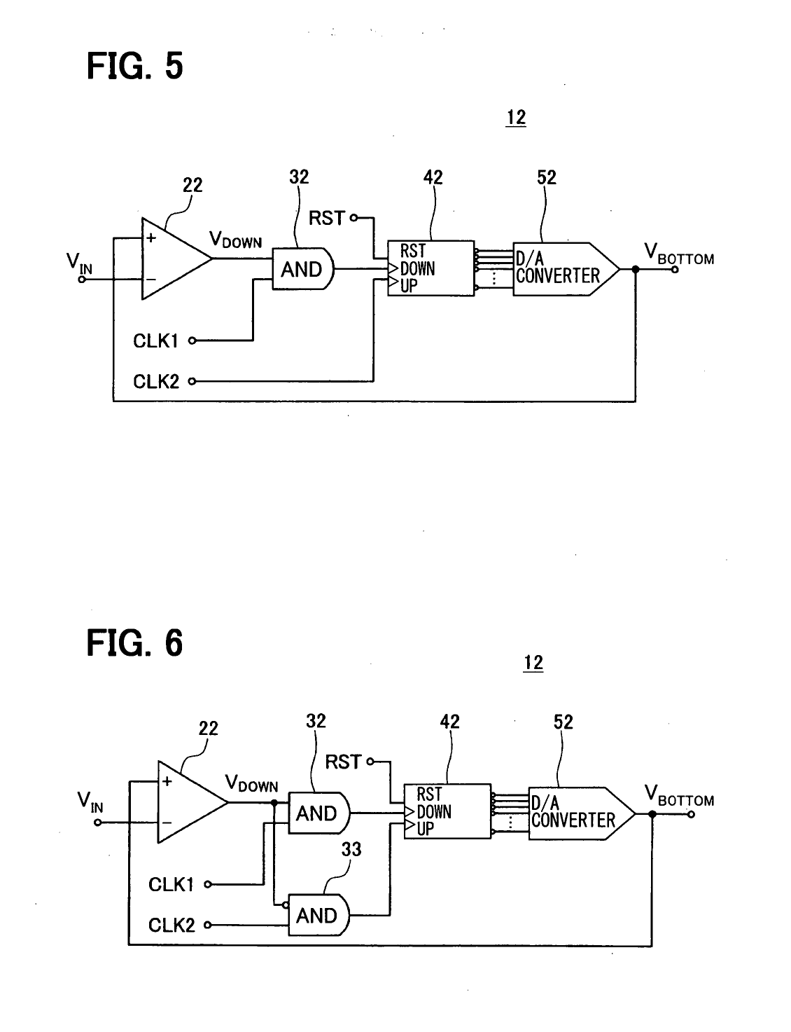

FIG. 5 shows a negative peak voltage detector circuit 12 for detecting a negative peak voltage, i.e., voltage convex downward. An input voltage V_{IN} is input into an inversion input terminal of a comparator 22, and an output voltage V_{BOTTOM} of a D/A conversion circuit 52 is input into a noninversion input terminal of the comparator 22. Further, an output of an up/down n-bit counter circuit 42 is inverted, and the inverted output is input into a D/A conversion circuit 52. The other parts in the negative peak voltage detector circuit 12 may be made similar to the positive peak voltage detector circuit 10.

When the input voltage V_{IN} is smaller than the output voltage V_{BOTTOM}, an output signal V_{DOWN} of the comparator 22 becomes high. When the output signal V_{DOWN} of the comparator 22 is high, the AND circuit 32 inputs the first clock signal CLK1 into an up-input terminal of the counter circuit 42. Therefore, when the input voltage V_{IN} is smaller than the output voltage V_{BOTTOM}, the counter value of the counter circuit 42 is added in synchronization with the first clock signal CLK1. However, because the output of the counter circuit 42 is inverted, the counter value of the counter circuit 42 is practically subtracted in synchronization with the first clock signal CLK1, when the input voltage V_{IN} is smaller than the output voltage V_{BOTTOM}. Thus, when the input voltage V_{IN} is smaller than the output voltage V_{BOTTOM}, the output voltage V_{BOTTOM} can be decreased in synchronization with the first clock signal CLK1. Therefore, the output voltage V_{BOTTOM} can be decreased to follow a rapid decreasing of the input voltage V_{IN}.

Further, the counter value of the counter circuit 42 is practically added by using the second clock signal CLK2 having a wave period longer than that of the first clock signal CLK1. Therefore, the output voltage V_{BOTTOM} of the D/A conversion circuit 52 can be increased. Thus, the output voltage V_{BOTTOM} can be increased to follow a slow increasing of the input voltage V_{IN}.

According to the negative peak voltage detector circuit 12, the output voltage V_{BOTTOM} can follow both of a rapid variation and a slow variation of the input voltage V_{IN} by using the first and second clock signals CLK1, CLK2. Due to the negative peak voltage detector circuit 12, the negative peak voltage of the input voltage V_{IN} can be accurately detected.

FIG. 6 shows a modification of the negative peak voltage detector circuit 12. In the modification, the circuit 12 further includes another AND circuit 33, i.e., second AND circuit 33. The second AND circuit 33 has two input terminals. An inversion signal inverted of the output signal V_{DOWN} of the comparator 22 is input into one input terminal of the second AND circuit 33, and the second clock signal CLK2 is input into the other input terminal of the second AND circuit 33.

According to the modification, the counter circuit 42 practically adds the counter value in synchronization with the second clock signal CLK2 only when the output signal V_{DOWN} of the comparator 22 is low. In other words, when the output signal V_{DOWN} of the comparator 20 is high, that is when the input voltage V_{IN} is smaller than the output voltage V_{BOTTOM}, the counter value of the counter circuit 42 is not added. Therefore, when the input voltage V_{IN} is rapidly decreased, the output voltage V_{BOTTOM} can accurately follow the rapid decreasing of the input voltage V_{IN}.

### Second Embodiment

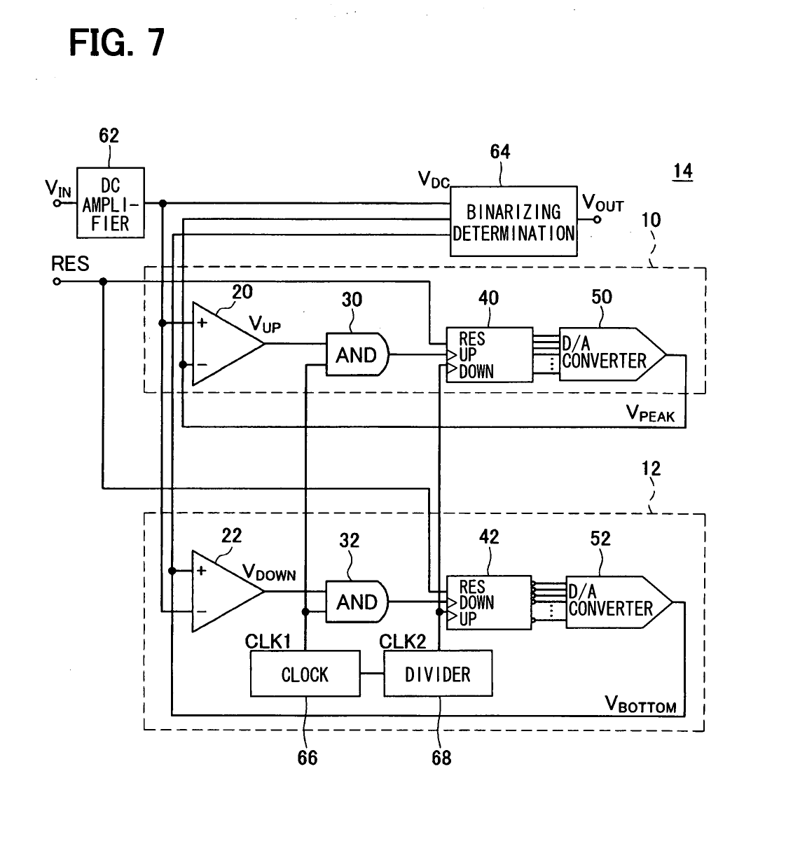

FIG. 7 shows a binarizing circuit 14. The binarizing circuit 14 includes the positive peak voltage detector circuit 10 shown in FIG. 1, the negative peak voltage detector circuit 12 shown in FIG. 5, a binarizing determination circuit 64 and a direct-current (DC) amplifier circuit 62. The binarizing circuit 14 further includes a clock circuit 66 and a frequency divider circuit 68. The clock circuit 66 generates a first clock signal CLK1. The frequency divider circuit 68 converts the first clock signal CLK1 having high-frequency into a second clock signal CLK2 having a low-frequency. The DC amplifier circuit 62 amplifies an input voltage V_{IN} into an input voltage V_{DC}.

The binarizing determination circuit 64 calculates an intermediate value as a threshold voltage by using the output voltage V_{PEAK} detected by the positive peak voltage detector circuit 10 and the output voltage V_{BOTTOM} detected by the negative peak voltage detector circuit 12. The binarizing determination circuit 64 determines the input voltage V_{DC} to be high or low by using the threshold voltage. Thus, the binarizing determination circuit 64 can convert the input voltage V_{DC} into a digital signal V_{OUT}.

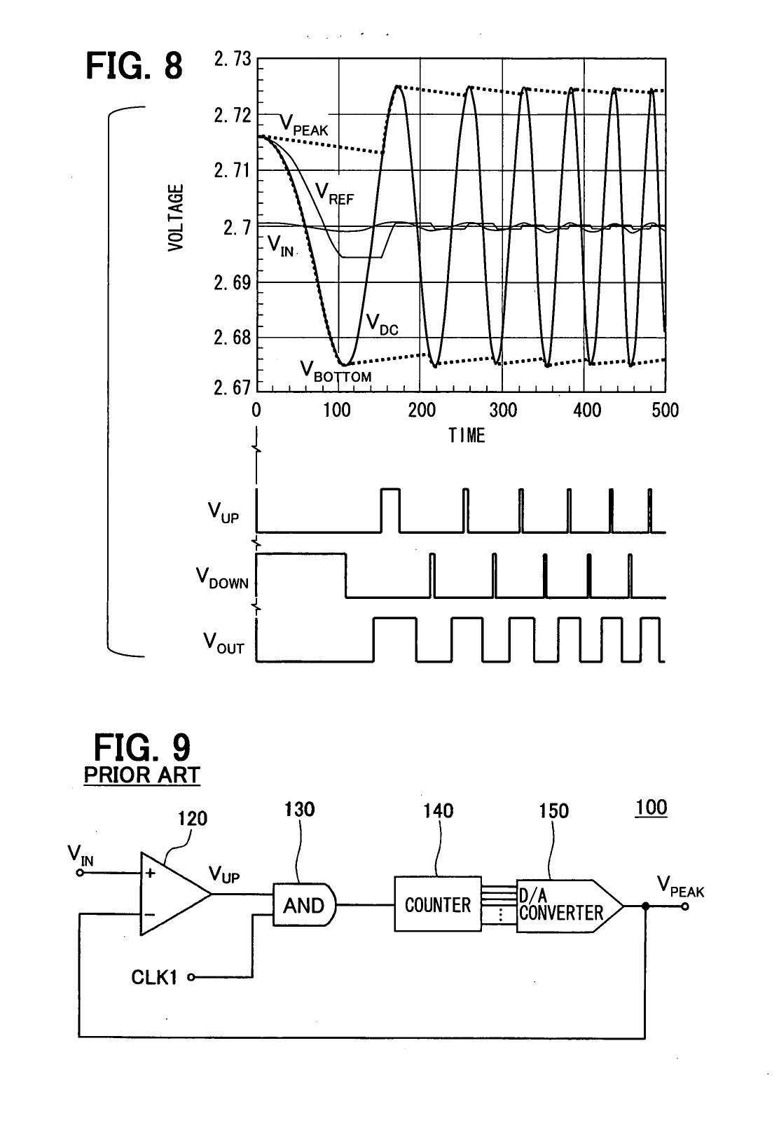

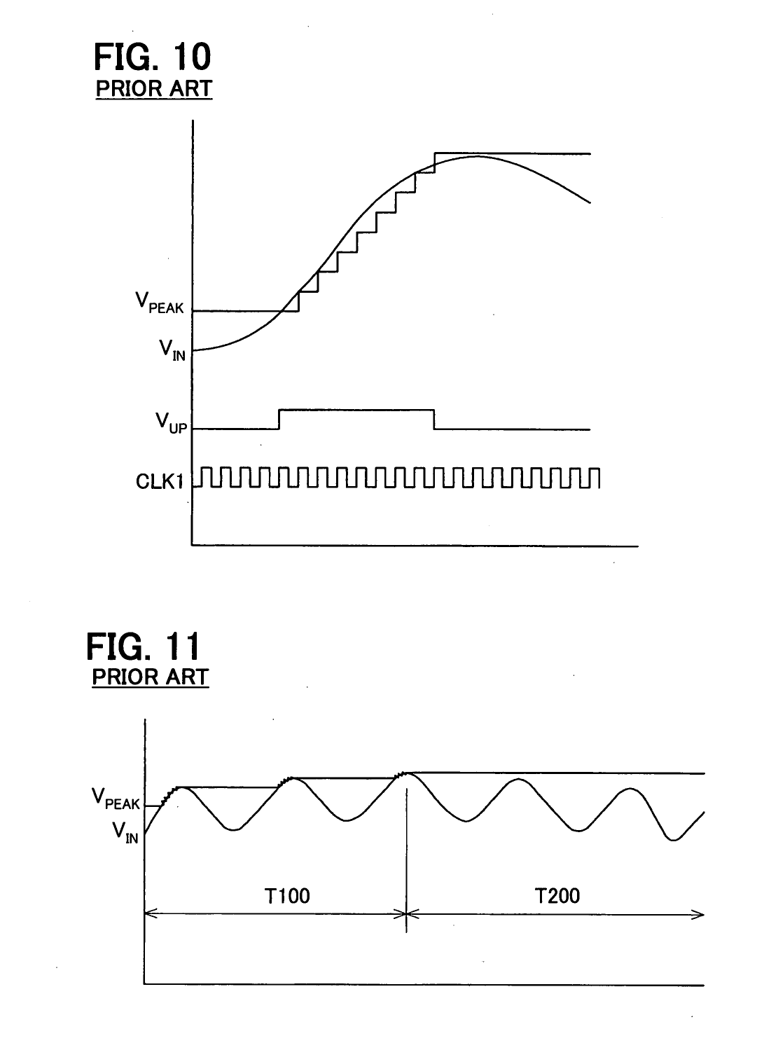

FIG. 8 shows a waveform chart of the binarizing circuit 14. The DC amplifier circuit 62 amplifies the input voltage V_{IN} into the amplified input voltage V_{DC}, which has an alternating waveform varying in a range between about 2.67V and about 2.73V, for example.

The positive peak voltage detector circuit 10 can accurately detect the output voltage V_{PEAK} corresponding to the positive peak voltage, and the negative peak voltage detector circuit 12 can accurately detect the output voltage V_{BOTTOM} corresponding to the negative peak voltage. Therefore, an accurate threshold voltage V_{REF} can be provided by the determination circuit 64 using the accurate output voltages V_{PEAK}, V_{BOTTOM}. Thus, the amplified input voltage V_{DC} can be determined to be high or low by using the accurate threshold voltage V_{REF}, so that the input voltage V_{DC} can be converted into the digital signal V_{OUT}.

Due to the circuits 10, 12, the output voltages V_{PEAK}, V_{BOTTOM} are the accurate peak voltages, when the input voltage V_{IN} has a slow varying part. Because the binarizing circuit 14 is constructed by the circuits 10, 12, the slow varying part of the input voltage V_{IN} can be also reflected in the threshold voltage V_{REF} provided by the output voltages V_{PEAK}, V_{BOTTOM}. Thus, the slow varying part of the input voltage V_{IN} can be also reflected in the digital signal V_{OUT} output from the binarizing circuit 14. Thus, the binarizing circuit 14 can accurately binarize the input voltage V_{IN} having a rapidly varying part and the slowly varying part.

Such changes and modifications are to be understood as being within the scope of the present invention as defined by the appended claims. While the invention has been described with reference to a preferred embodiment thereof, it is to be understood that the invention is not limited to the preferred embodiment and constructions. The invention is intended to cover various modification and equivalent arrangements. The invention is intended to cover various combinations and configurations, which are preferred, other combinations and configurations, including more, less or only a single element, are also within the spirit and scope of the invention.

What is claimed is:

1. A peak voltage detector circuit for detecting a peak voltage of an input voltage comprising:
a comparator having a first input terminal and a second input terminal, wherein the input voltage is input into the first input terminal of the comparator;
a first clock signal generating circuit for generating a first clock signal;
a second clock signal generating circuit for generating a second clock signal;
a counter circuit for counting up a counter value in synchronization with the first clock signal, when an output signal output from the comparator is in a first state, wherein the counter circuit counts down the counter value in synchronization with the second clock signal; and
a digital-analog conversion circuit for outputting an output voltage corresponding to the counter value of the counter circuit, wherein the output voltage of the digital-analog conversion circuit is input into the second input terminal of the comparator, wherein
the first clock signal has a wave period shorter than that of the second clock signal.

2. The peak voltage detector circuit according to claim 1, wherein
the counter circuit counts up the counter value in synchronization with the first clock signal, when the output signal output from the comparator is in the first state, and
the counter circuit counts down the counter value in synchronization with the second clock signal, when the output signal output from the comparator is in a second state opposite to the first state.

3. The peak voltage detector circuit according to claim 1, wherein the input voltage has an alternating waveform.

4. A peak voltage detector circuit for detecting a positive peak voltage of an input voltage comprising:
a comparator having a noninversion input terminal and an inversion input terminal, wherein the input voltage is input into the noninversion input terminal of the comparator;
a first clock signal generating circuit for generating a first clock signal;
a second clock signal generating circuit for generating a second clock signal;
a counter circuit for adding a counter value in synchronization with the first clock signal, when an output signal output from the comparator is high, wherein the counter circuit subtracts the counter value in synchronization with the second clock signal; and
a digital-analog conversion circuit for outputting an output voltage corresponding to the counter value of the counter circuit, wherein the output voltage of the digital-analog conversion circuit is input into the inversion input terminal of the comparator, wherein
the first clock signal has a wave period shorter than that of the second clock signal.

5. The peak voltage detector circuit according to claim 4, wherein
the counter circuit subtracts the counter value in synchronization with the second clock signal, when the output signal output from the comparator is low.

6. The peak voltage detector circuit according to claim 4, wherein the input voltage has an alternating waveform.

7. A peak voltage detector circuit for detecting a negative peak voltage of an input voltage comprising:
a comparator having a noninversion input terminal and an inversion input terminal, wherein the input voltage is input into the inversion input terminal of the comparator;
a first clock signal generating circuit for generating a first clock signal;
a second clock signal generating circuit for generating a second clock signal;
a counter circuit for subtracting a counter value in synchronization with the first clock signal, when an output signal output from the comparator is high, wherein the counter circuit adds the counter value in synchronization with the second clock signal; and
a digital-analog conversion circuit for outputting an output voltage corresponding to the counter value of the counter circuit, wherein the output voltage of the digital-analog conversion circuit is input into the noninversion input terminal of the comparator, wherein
the first clock signal has a wave period shorter than that of the second clock signal.

8. The peak voltage detector circuit according to claim 7, wherein
the counter circuit adds the counter value in synchronization with the second clock signal, when the output signal output from the comparator is low.

9. The peak voltage detector circuit according to claim 7, wherein the input voltage has an alternating waveform.

10. A binarizing circuit for converting an input voltage having an alternating waveform into a digital signal, wherein the binarizing circuit includes the peak voltage detector circuit according to claim 4 and the peak voltage detector circuit according to claim 7, the binarizing circuit further comprising:
a determination circuit for providing a threshold voltage based on a positive peak voltage provided by the peak voltage detector circuit according to claim 4 and a negative peak voltage provided by the peak voltage detector circuit according to claim 7, wherein
the determination circuit determines the input voltage to be high or low based on the provided threshold voltage.
